(19) United States
(12) Patent Application Publication
(10) Pub. No.: US 2024/0429315 A1
(43) Pub. Date: Dec. 26, 2024

(54) SEMICONDUCTOR DEVICE AND FABRICATION METHOD THEREOF

(71) Applicant: Vanguard International Semiconductor Corporation, Hsinchu (TW)

(72) Inventors: Wen-Shan Lee, Hsinchu City (TW); Chung-Yeh Lee, Hsinchu County (TW); Fu-Hsin Chen, Hsinchu County (TW)

(73) Assignee: Vanguard International Semiconductor Corporation, Hsinchu (TW)

(21) Appl. No.: 18/213,893

(22) Filed: Jun. 26, 2023

(51) Int. Cl. H01L 29/78; H01L 21/265; H01L 29/06; H01L 29/66

(52) U.S. Cl. CPC H01L 29/7813; H01L 21/265; H01L 29/0611; H01L 29/66734

(57) ABSTRACT

A semiconductor device includes a trench in a substrate, a gate electrode in the trench, a source contact region on a first surface of the substrate, a drain contact region on a second surface of the substrate, a heavily doped region directly below the trench, and a current spreading layer in the substrate to surround the bottom of the trench and the heavily doped region. The heavily doped region has a first conductivity type, and the width of the heavily doped region is smaller than the width of the trench in a first direction. The current spreading layer has a second conductivity type and a gradual doping concentration that is gradually increased along the first direction from the heavily doped region to the outside of the current spreading layer.

### BACKGROUND OF THE INVENTION

### 1. Field of the Invention

The present disclosure relates generally to semiconductor technology, and more particularly to a semiconductor device including trench power transistors and a fabrication method thereof.

### 2. Description of the Prior Art

Power transistors are usually used in power electronic systems as power switches, converters and other power components. Power transistors are typically operated under high voltage and high metal-oxide-semiconductor current conditions. Power field-effect-transistors (power MOSFETs) are common power transistors, which may include a horizontal structure such as a laterally-diffused metal-oxide-semiconductor (LDMOS) field-effect-transistor (FET), and a vertical structure such as a planar gate MOSFET or a trench gate MOSFET. For the trench gate MOSFET, a gate is disposed in a trench. Compared with the planar gate MOSFET, the trench gate MOSFET has the advantages of reducing the size of the element unit and reducing the parasitic capacitance thereof. However, the conventional trench gate MOSFETs still cannot fully satisfy the various requirements in power electronic applications, such as the requirements for the on-state resistance (Ron), the breakdown voltage and the reliability.

### SUMMARY OF THE INVENTION

In view of this, the present disclosure provides a semiconductor device and a fabrication method thereof, where a heavily doped region is disposed directly below a trench gate to be an electric field shielding structure. The width of the heavily doped region is reduced to be smaller than the width of a trench having the trench gate therein. In addition, a current spreading layer is disposed to surround the bottom of the trench and the heavily doped region. The current spreading layer has a laterally gradual doping concentration. Therefore, the breakdown voltage and the reliability of the semiconductor device are improved.

According to an embodiment of the present disclosure, a semiconductor device is provided and includes a substrate, a trench, a gate electrode, a source contact region, a drain contact region, a heavily doped region, and a current spreading layer. The substrate has a first surface and a second surface. The trench is disposed in the substrate and the gate electrode is disposed in the trench. The source contact region is disposed on the first surface of the substrate, and the drain contact region is disposed on the second surface of the substrate. The heavily doped region has a first conductivity type and is disposed directly below the trench. The width of the heavily doped region is smaller than the width of the trench in a first direction. In addition, the current spreading layer has a second conductivity type and is disposed in the substrate to surround the bottom of the trench and the heavily doped region. The current spreading layer has a gradual doping concentration that is gradually increased along the first direction from the heavily doped region to the outside of the current spreading layer.

According to an embodiment of the present disclosure, a method of fabricating a semiconductor device is provided and includes the following steps. A wafer is provided and includes a drain contact region, a first epitaxial layer and a second epitaxial layer stacked from bottom to top in sequence. A patterned mask is formed on the second epitaxial layer and includes a plurality of openings, where the widths of the plurality of openings are increased in sequence from the inside to the outside of the patterned mask along a first direction. An ion implantation process is performed on the second epitaxial layer through the plurality of openings of the patterned mask to form a plurality of doped regions. A third epitaxial layer is deposited on the second epitaxial layer, and a current spreading layer is formed from the plurality of doped regions and the second epitaxial layer, where the current spreading layer has a gradual doping concentration that is gradually increased from the inside to the outside of the current spreading layer along the first direction. A source contact region is formed in the third epitaxial layer. A trench is formed to pass through the third epitaxial layer and to reach into the current spreading layer. A heavily doped region is formed directly below the trench, where the width of the heavily doped region is smaller than the width of the trench in the first direction. In addition, a gate electrode is formed in the trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to an embodiment of the present disclosure.

FIG. 2 is a schematic cross-sectional view of a portion of a semiconductor device according to an embodiment of the present disclosure, where the dimensions of some features of the semiconductor device are indicated and two repeating units are shown.

FIG. 3, FIG. 4, FIG. 5, FIG. 6, FIG. 7, FIG. 8, FIG. 9 and FIG. 10 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the s appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device including trench power transistors and a fabrication method thereof. One of the purposes of the present disclosure is to reduce the resistance of an junction field effect transistor (JFET) effect produced at the bottom of a trench through reducing the width of a heavily doped region to be smaller than the width of the trench, where the heavily doped region is disposed directly below the trench and used as an electric field shielding structure. In addition, the electric field intensity at the bottom of a trench gate is effectively reduced through a current spreading layer (CSL) having a laterally gradual doping concentration and disposed to surround the bottom of the trench and the heavily doped region. Therefore, the breakdown voltage and the reliability of the semiconductor device are improved.

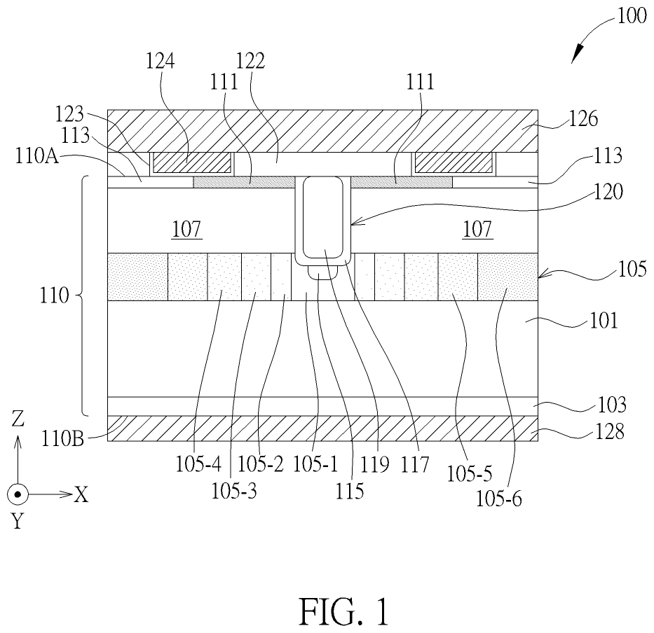

FIG. 1 is a schematic cross-sectional view of a semiconductor device 100 according to an embodiment of the present disclosure. The semiconductor device 100 includes a substrate 110 having a first surface 110A and a second surface 110B, where the first surface 110A is such as a front surface and the second surface 110B is such as a back surface opposite to the first surface 110A. The substrate 110 may include a drain contact region 103 disposed on the second surface 110B of the substrate 110. The drain contact region 103 has a second conductivity type, for example an N-type heavily doped region (N⁺). The substrate 110 further includes a first epitaxial layer 101 deposited on the drain contact region 103. The first epitaxial layer 101 has the second conductivity type, for example an N-type epitaxial layer. In addition, the semiconductor device 100 includes a source contact region 111 disposed on the first surface 110A of the substrate 110. The source contact region 111 has the second conductivity type, for example an N-type heavily doped region (N⁺). In some embodiments, the composition of the substrate 110 is, for example, silicon carbide (SiC). As shown in FIG. 1, the semiconductor device 100 further includes a trench 120 disposed in the substrate 110. A gate electrode 119 is disposed in the trench 120, and a gate dielectric layer 117 is conformally disposed on the sidewalls and the bottom surface of the trench 120 to surround the gate electrode 119, thereby constructing a trench power transistor such as a trench power MOSFET of the semiconductor device 100. In addition, the semiconductor device 100 includes a well region 107 disposed in the substrate 110 and abutting the sides of the trench 120. The well region 107 has a first conductivity type, for example a P-type well region (PW). The source contact region 111 is disposed in the well region 107. The semiconductor device 100 further includes a bulk contact region 113 disposed in the well region 107 and abutting the source contact region 111. The bulk contact region 113 has the first conductivity type, for example a P-type heavily doped region (P⁺). In addition, an interlayer dielectric (ILD) layer 122 is formed on the first surface 110A of the substrate 110. A via 124 is formed in the ILD layer 122, and a barrier layer 123 may be disposed in a contact opening of the ILD layer 122 as a liner to surround the via 124. A source electrode 126 is formed on the ILD layer 122 and electrically coupled to the source contact region 111 and the bulk contact region 113 through the via 124.

Still referring to FIG. 1, the semiconductor device 100 further includes a heavily doped region 115 disposed directly below the trench 120. The heavily doped region 115 has the first conductivity type, for example a P-type heavily doped region (P⁺). The heavily doped region 115 may be used as an electric field shielding structure to reduce the electric field at the bottom of a trench gate. According to some embodiments of the present disclosure, in a first direction (for example, the X-axis direction), the width of the heavily doped region 115 is smaller than the width of the trench 120, and the bottom corners of the trench 120 are not, covered by the heavily doped region 115. In addition, the semiconductor device 100 further includes a current spreading layer 105 disposed in the substrate 110, where the current spreading layer 105 surrounds the bottom of the trench 120 and the heavily doped region 115. The first epitaxial layer 101 is located between the drain contact region 103 and the current spreading layer 105, and the current spreading layer 105 is located between the well region 107 and the first epitaxial layer 101. According to some embodiments of the present disclosure, the current spreading layer 105 has a gradual doping concentration along the first direction (such as the X-axis direction), which is produced by adjusting the sizes of openings of a patterned mask used for an ion implantation process to be changed gradually. The gradual doping concentration is increased gradually from the heavily doped region 115 to the outside of the current spreading layer 105, i.e., the current spreading layer 105 has a laterally gradual doping concentration.

As shown in FIG. 1, in one embodiment, the current spreading layer 105 may include multiple regions 105-1, 105-2, 105-3, 105-4, 105-5 and 105-6. The current spreading layer 105 has the second conductivity type (such as N type), i.e., these regions 105-1 to 105-6 all have the second conductivity type (such as N type). Along the first direction (such as the X-axis direction), the doping concentrations of these regions 105-1 to 105-6 are increased in sequence from the inner region 105-1 to the outer region 105-6, where the inner region 105-1 has the lowest doping concentration in the current spreading layer 105, and the outer region 105-6 has the highest doping concentration in the current spreading layer 105. In addition, the inner region 105-1 is in a direct contact with the heavily doped region 115 and the bottom corners of the trench 120. The gate dielectric layer 117 is located between the inner region 105-1 and the gate electrode 119. Moreover, the lowest doping concentration of the inner region 105-1 is lower than the doping concentration of the first epitaxial layer 101. The highest doping concentration of the outer region 105-6 is higher than the doping concentration of the first epitaxial layer 101. The doping concentrations of the other regions 105-2 to 105-5 are between the lowest doping concentration of the inner region 105-1 and the highest doping concentration of the outer region 105-6. In some embodiments, the doping concentrations of the inner region 105-1 to the region 105-3 are, for example, in the range of about 1E15 to about 1E16 atoms/cm³, and the doping concentrations of the region 105-4 to the outer region 105-6 are, for example, in the range of about 1E16 to about 1E17 atoms/cm³, but not limited thereto. The number of the regions and the range of the doping concentrations of the regions of the current spreading layer 105 may be adjusted according to the electrical requirements of the semiconductor device 100 to produce the laterally gradual doping concentration.

In the conventional trench power MOSFETs, the known shielding structure located below the bottom of the trench gate is usually extended laterally to cover the bottom corners of the trench to reduce the electric field at the bottom corners of the trench. However, the known shielding structure also generates the junction field effect transistor (JFET) effect between the well region and the sidewalls of the trench at the bottom corners of the trench, and a higher resistance of the JFET is produced. Therefore, in the conventional trench power MOSFETs, the conventional current spreading layer in contact with the known shielding structure needs to have a much higher doping concentration than that of the epitaxial layer in order to reduce the resistance produced by the JFET. However, a higher electric field is also generated at the junction of the conventional current spreading layer having the higher doping concentration and the gate dielectric layer located on the sidewalls of the trench, and the breakdown voltage and the reliability of the conventional trench power MOSFETs are reduced.

According to some embodiments of the present disclosure, the width of the heavily doped region 115 used as an electric field shielding structure in the semiconductor device 100 is smaller than the width of the trench 120, and the heavily doped region 115 is not extended laterally to the bottom corners of the trench 120. As a result, the JFET effect generated at the bottom corners of the trench 120 is greatly reduced, thereby reducing the resistance generated by the JFET. In addition, in the semiconductor device 100 of some embodiments of the present disclosure, the inner region 105-1 of the current spreading layer 105 has the lowest doping concentration, which is much lower than the doping concentration of the first epitaxial layer 101. Therefore, the inner region 105-1 of the second conductivity type having the lowest doping concentration provides an electric field shielding effect similar to that of the heavily doped region 115 of the first conductivity type. In addition, the inner region 105-1 is in a direct contact with the heavily doped region 115 and surrounds the bottom of the trench 120. Through the combination of the heavily doped region 115 having a reduced width and the inner region 105-1 of the current spreading layer 105 having a reduced doping concentration, the electric field at the bottom of the trench gate is effectively reduced, thereby increasing the breakdown voltage of the semiconductor device 100 and improving the reliability of the gate dielectric layer 117. In addition, the outer region 105-6 of the current spreading layer 105 has the highest doping concentration that is much higher than the doping concentration of the first epitaxial layer 101, so that an effect of spreading the current is achieved by the outer region 105-6 and the other regions 105-5 and 105-4 having the high doping concentrations to effectively reduce the impedance, thereby reducing the on-state resistance (Ron) of the semiconductor device 100. In addition, the current spreading layer 105 has a laterally gradual doping concentration, thereby avoiding sudden changes in the electric field strength of the semiconductor device 100 to further improve the reliability of the semiconductor device 100.

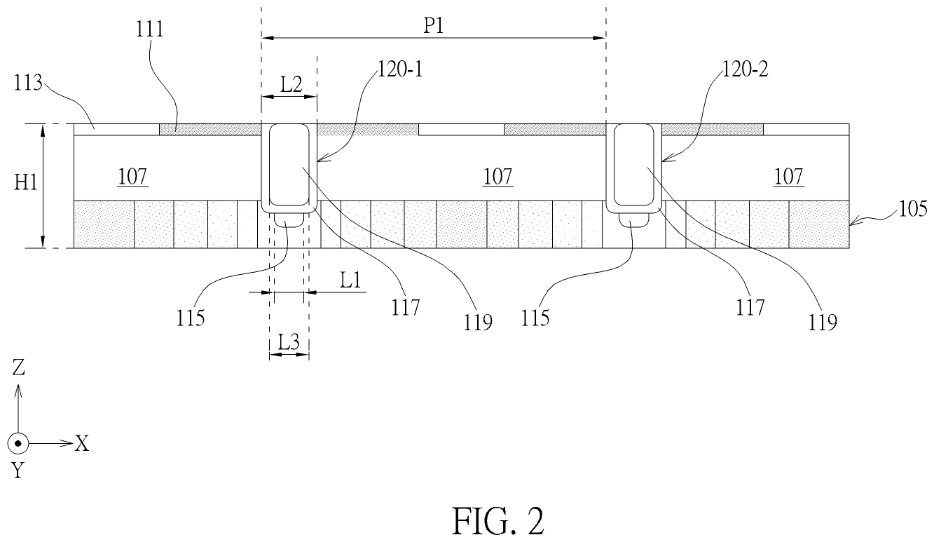

FIG. 2 is a schematic cross-sectional view of a portion of the semiconductor device 100 according to an embodiment of the present disclosure, which indicates the dimensions of the heavily doped region 115 and the trench 120 of the semiconductor device 100, and includes two repeating units 100U of the semiconductor device 100. Referring to FIG. 2, in the first direction (such as the X-axis direction), the heavily doped region 115 has a width L1, the trench 120 has a width L2, and the width L1 of the heavily doped region 115 is smaller than the width L2 of the trench 120. In addition, the trench 120 has a depth H1, and the width L1 of the heavily doped region 115 may be adjusted according to the actual conditions of the depth H1 and the width L2 of the trench 120. For example, when the depth H1 of the trench 120 is larger, the width L1 of the heavily doped region 115 may be increased or decreased accordingly. In addition, in the first direction (such as the X-axis direction), the width L1 of the heavily doped region 115 may be smaller than a width L3 of the gate electrode 119. The heavily doped region 115 provides sufficient electric field shielding effect to effectively reduce the electric field at the bottom of the gate electrode 119. As shown in FIG. 2, one gate electrode 119 is disposed in a trench 120-1 of one repeating unit 100U of the semiconductor device 100, and another gate electrode 119 is disposed in a trench 120-2 of another adjacent repeating unit 100U. The plurality of repeating units 100U of the semiconductor device 100 are all formed in the same substrate 110. In addition, there is a pitch P1 between the trench 120-1 and the adjacent trench 120-2. The width L1 of the heavily doped region 115 may be adjusted according to the pitch P1. For example, when the pitch P1 is smaller, the width L1 of the heavily doped the region 115 may be reduced accordingly.

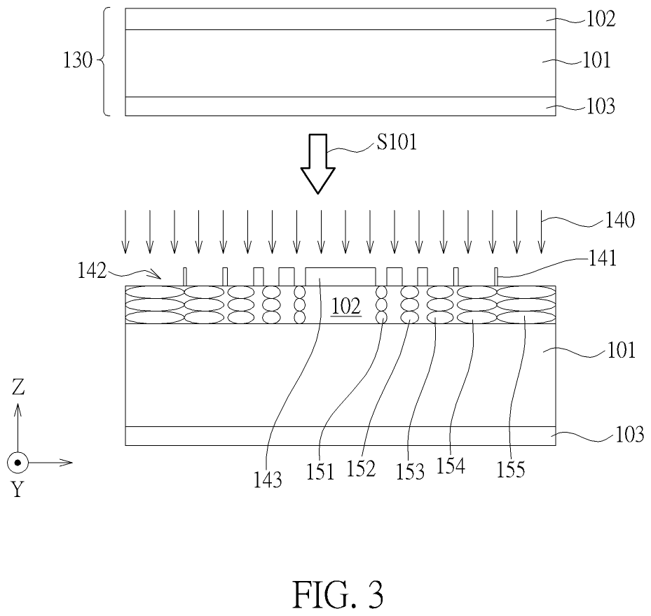

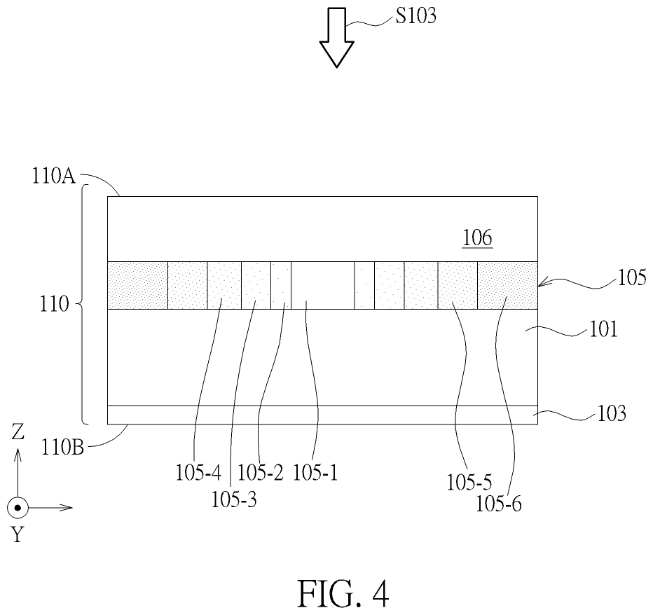

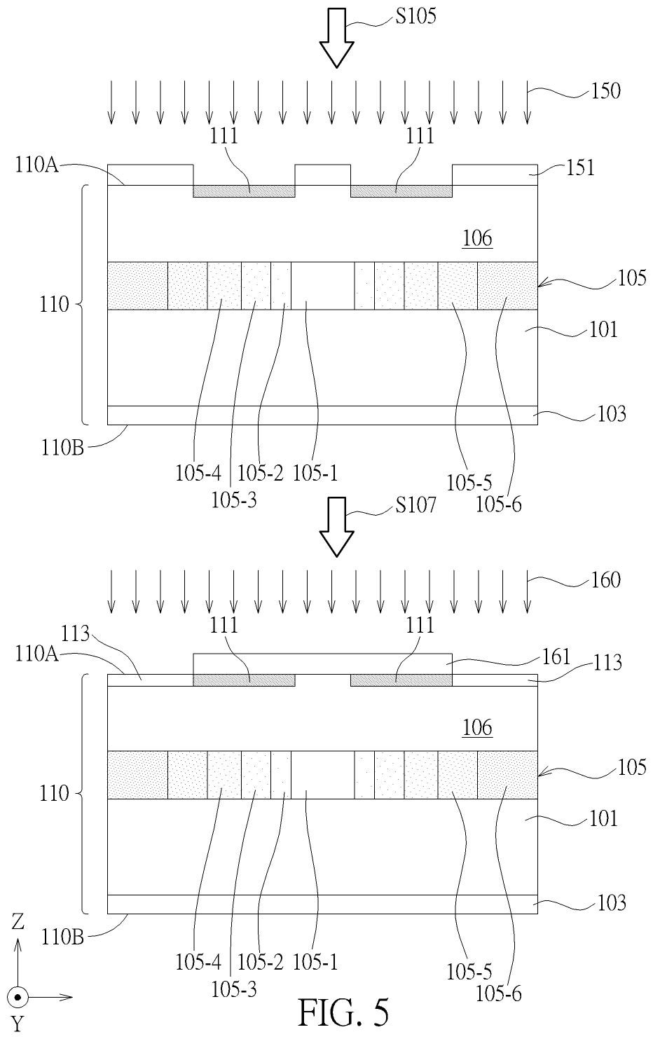

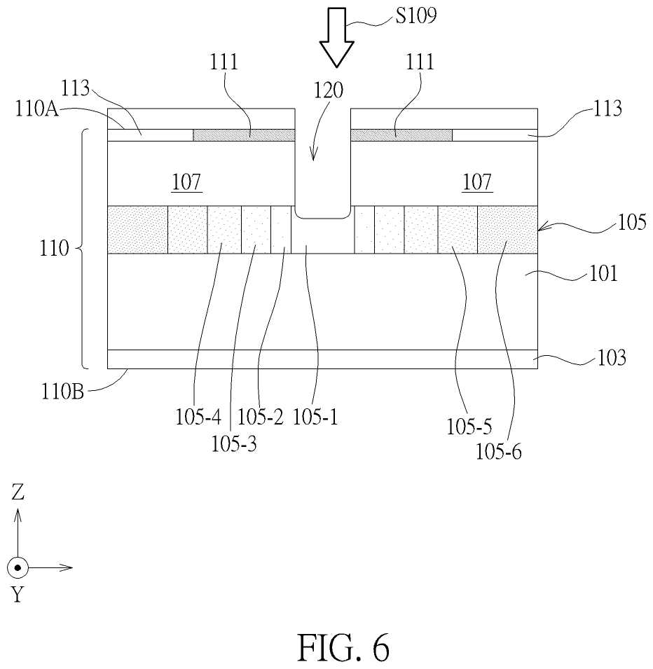

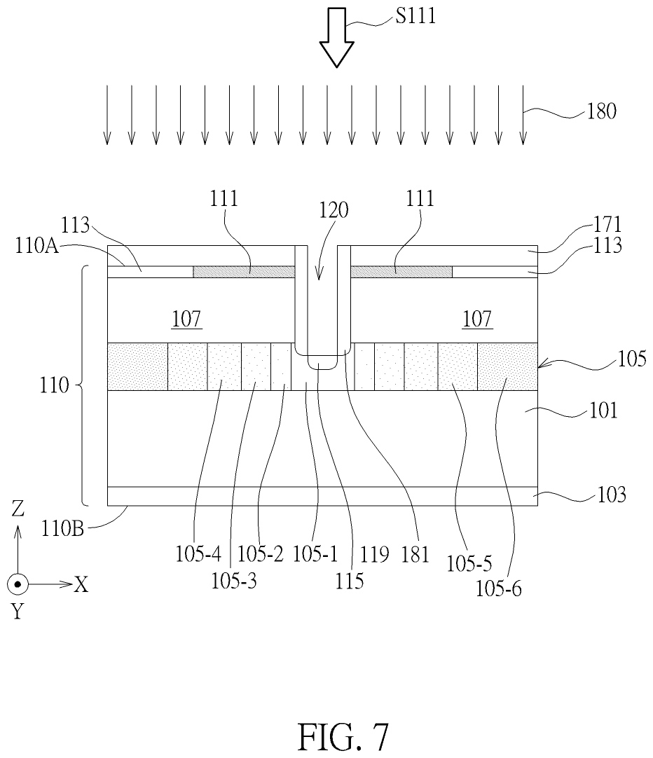

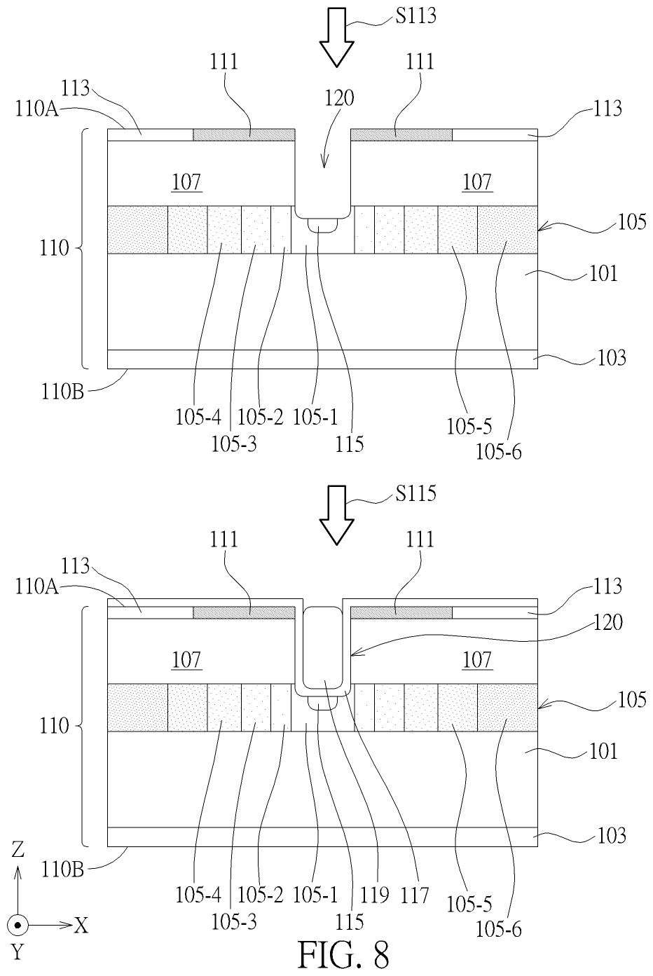

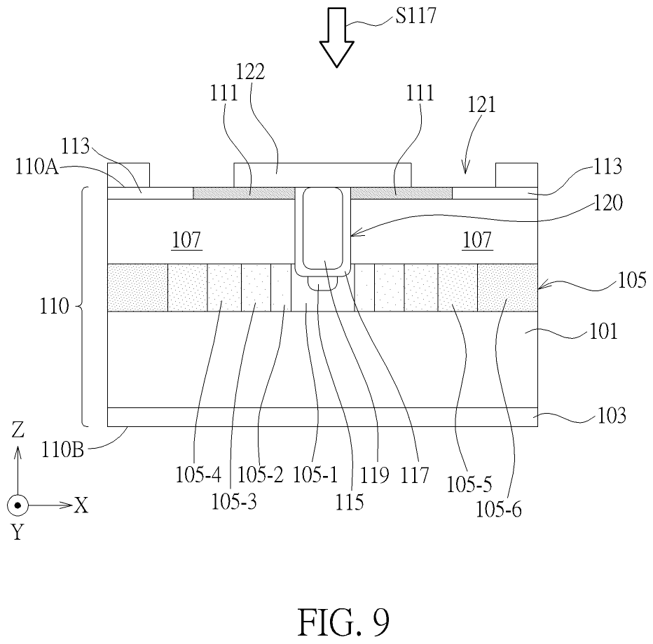

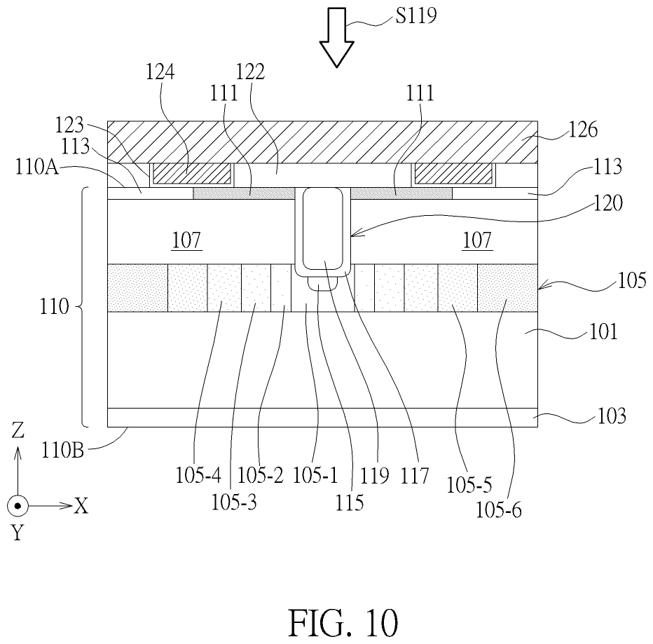

FIG. 3, FIG. 4, FIG. 5, FIG. 6, FIG. 7, FIG. 8, FIG. 9 and FIG. 10 are schematic cross-sectional views of some stages of a method of fabricating the semiconductor device 100 according to an embodiment of the present disclosure. Referring to FIG. 3, firstly, a wafer 130 is provided. In some embodiments, the wafer 130 may include the drain contact region 103, the first epitaxial layer 101, and a second epitaxial layer 102, which are stacked from bottom to top in sequence. The drain contact region 103, the first epitaxial layer 101 and the second epitaxial layer 102 all have the second conductivity type (such as N type), where the doping concentration of the second epitaxial layer 102 is higher than the doping concentration of the first epitaxial layer 101. In some embodiments, the composition of the wafer 130 is, for example, silicon carbide (SiC). The drain contact region 103 is, for example, an N-type heavily doped region (N⁺), which may be formed by using an ion implantation process to implant dopants of the second conductivity type (such as N type) on the back surface of the SiC semiconductor substrate to form the drain contact region 103. The first epitaxial layer 101 is, for example, an N-type SiC epitaxial layer, which may be formed by depositing a SiC epitaxial layer on the drain contact region 103 through an epitaxial growth process, and dopants of the second conductivity type (such as N type) are added during the epitaxial growth process to form the first epitaxial layer 101. The second epitaxial layer 102 is, for example, an N-type lightly doped SiC epitaxial layer, which may be formed by depositing a SiC epitaxial layer on the first epitaxial layer 101 through another epitaxial growth process, and dopants of the second conductivity type (such as N type) are added during the another epitaxial growth process to form the second epitaxial layer 102. The doping concentration of the second epitaxial layer 102 is higher than that of the first epitaxial layer 101. In some embodiments, the doping concentration of the first epitaxial layer 101 is, for example, about 1E14 to about 1E16 atoms/cm³, and the doping concentration of the second epitaxial layer 102 is, for example, about 1E15 to about 1E17 atoms/cm³, but not limited thereto.

Still referring to FIG. 3, next, in step S101, a patterned mask 141 is formed on the second epitaxial layer 102. In one embodiment, the patterned mask 141 is a hard mask having the composition of silicon oxide. A hard mask material layer may be deposited on the second epitaxial layer 102, and then the hard mask material layer is patterned by photolithography and etching processes to form the patterned mask 141. The patterned mask 141 includes multiple openings 142 to expose multiple regions of the second epitaxial layer 102, respectively. The openings 142 located on the inner region and the outer region of the second epitaxial layer 102 have different widths. In the first direction (such as the X-axis direction), the widths of these openings 142 are increased in sequence from the inside to the outside of the patterned mask 141, where the opening 142 located on the inner region of the second epitaxial layer 102 has the smallest width, and the opening 142 located on the outer region of the second epitaxial layer 102 has the maximum width. In the step S101, an ion implantation process 140 is performed on the second epitaxial layer 102 through the openings 142 of the patterned mask 141 to implant dopants of the second conductivity type (such as N type) into the second epitaxial layer 102 to form multiple doped regions 151, 152, 153, 154 and 155 of the second conductivity type such as N type. These doped regions 151 to 155 have the same doping concentration and are laterally separated from each other in the second epitaxial layer 102. These doped regions 151 to 155 located in the inner region and the outer region of the second epitaxial layer 102 have different widths. In addition, the distances between any two adjacent doped regions of these doped regions 151 to 155 are different from each other. Moreover, the patterned mask 141 includes multiple shielding portions 143. These shielding portions 143 on the inner region and the outer region of the second epitaxial layer 102 have different widths. In the first direction, the widths of these shielding portions 143 are decreased in sequence from the inside to the outside of the patterned mask 141. The shielding portion 143 located on the inner region of the second epitaxial layer 102 has the largest width, and the shielding portion 143 located on the outer region of the second epitaxial layer 102 has the smallest width. After the ion implantation process 140 is performed, the patterned mask 141 may be removed by a stripping process, for example, an ashing process or soaking in a solvent may be used to strip the patterned mask 141 from the second epitaxial layer 102.

Next, referring to FIG. 4, in step S103, a third epitaxial layer 106 is deposited on the second epitaxial layer 102 of FIG. 3 through an epitaxial growth process, and the third epitaxial layer 106 has the first Conductivity type (such as P-type). In one embodiment, the third epitaxial layer 106 is, for example, a P-type SiC epitaxial layer, and dopants of the first conductivity type (such as P-type) may be added during the epitaxial growth process to form the third epitaxial layer 106. The epitaxial growth process for depositing the third epitaxial layer 106 is performed at a high temperature, for example, at a temperature of about 1600° C. to about 1700° C. After the deposition of the third epitaxial layer 106, the dopants in these doped regions 151 to 155 are diffused in the second epitaxial layer 102 to form multiple regions 105-1, 105-2, 105-3, 105-4, 105-5 and 105-6 of the current spreading layer 105 as shown in FIG. 4. Referring to both FIG. 3 and FIG. 4, since the multiple openings 142 and the multiple shielding portions 143 of the patterned mask 141 located on the inner region and the outer region of the second epitaxial layer 102 all have different widths, the multiple doped regions 151 to 155 formed in the second epitaxial layer 102 also have different widths, and the lateral distances between these doped regions 151 to 155 are also different from each other. After depositing the third epitaxial layer 106, the dopants in these doped regions 151 to 155 are diffused in the second epitaxial layer 102, where a portion of the second epitaxial layer 102 directly below the shielding portion 143 having the maximum width produces an inner region 105-1 of the current spreading layer 105 having the lowest doping concentration, and the lowest doping concentration of the inner region 105-1 is substantially the same as the doping concentration of the second epitaxial layer 102. In addition, the doped region 151 with a smaller width and a larger distance from the other adjacent doped regions produce the region 105-2 having the second lowest doping concentration. The doped region 155 with the largest width and directly below the opening 142 with the largest width produces the outer region 150-6 of the current spreading layer 150 having the highest doping concentration. Another doped region 154 with the second largest width and a smaller distance from the other adjacent doped regions produce the region 105-5 having the second highest doping concentration. As a result, the multiple regions 105-1 to 105-6 with gradually changed doping concentrations as shown in FIG. 4 are formed to construct the current spreading layer 105, and the doping concentrations of these regions 105-1 to 105-6 are increased gradually from the inside to the outside of the current spreading layer 105.

According to an embodiment of the present disclosure, the ion implantation process 140 is performed on the second epitaxial layer 102 by using the patterned mask 141 of FIG. 3, and then the dopants in the multiple doped regions 151 to 155 are diffused in the second epitaxial layer 102 through the epitaxial growth process temperature for depositing the third epitaxial layer 106, thereby forming the current spreading layer 105 from these doped regions 151 to 155 and the second epitaxial layer 102, where the current spreading layer 105 has a laterally gradual doping concentration. In the first direction (for example, the X-axis direction), the laterally gradual doping concentration is gradually increased from the inner side to the outer side of the current spreading layer 105.

Next, referring to FIG. 5, in step S105, a patterned mask 151 is formed on the third epitaxial layer 106. In one embodiment, the patterned mask 151 is a hard mask having the composition of silicon oxide, and the patterned mask 151 may be formed by deposition, photolithography and etching processes. The patterned mask 151 includes multiple openings to respectively expose the predetermined regions of forming source contact regions. In the step S105, an ion implantation process 150 is performed on the third epitaxial layer 106 through the multiple openings of the patterned mask 151, and dopants of the second conductivity type (such as N type) are implanted into the third epitaxial layer 106 to form the source contact regions 111. Afterwards, the patterned mask 151 is removed by a stripping process.

Still referring to FIG. 5, in step S107, another patterned mask 161 is formed on the third epitaxial layer 106. In one embodiment, the patterned mask 161 is a hard mask having composition of silicon oxide, and the patterned mask 161 may be formed by deposition, photolithography and etching processes. The patterned mask 161 includes multiple openings to respectively expose the predetermined regions of forming bulk contact regions. In the step S107, an ion implantation process 160 is performed on the third epitaxial layer 106 through the multiple openings of the patterned mask 161, and dopants of the first conductivity type (such as P type) are implanted into the third epitaxial layer 106 to form the bulk contact regions 113. In one embodiment, the bulk contact regions 113 abut the source contact regions 111, respectively. Afterwards, the patterned mask 161 is removed by a stripping process.

Next, referring to FIG. 6, in step S109, a patterned mask 171 is formed to cover the source contact regions 111 and the bulk contact regions 113. In one embodiment, the patterned mask 171 is a hard mask having the composition of silicon oxide, and the patterned mask 171 may be formed by deposition, photolithography and etching processes. The patterned mask 171 includes multiple openings to respectively expose the predetermined regions of forming trenches. In the step S109, an etching process is performed on the third epitaxial layer 106 of FIG. 5 through the multiple openings of the patterned mask 171 to form the trenches 120, where the portions of the third epitaxial layer 106 located on the sides of the trench 120 are referred to as well regions 107. In one embodiment, the trench 120 passes through the third epitaxial layer 106 and is extended downward into the current spreading layer 105, where the bottom of the trench 120 is located at a depth of the inner region 105-1. According to some embodiments of the present disclosure, the bottom of the trench 120 is surrounded by the inner region 105-1 having the lowest doping concentration in the current spreading layer 105.

Next, referring to FIG. 7, in step S111, the patterned mask 171 is remained on the source contact regions 111 and the bulk contact regions 113, and a spacer material layer is conformally deposited on the sidewalls and the bottom surface of the trench 120 and on the surface of the patterned mask 171. Then, the portions of the spacer material layer located on the top surface of the patterned mask 171 and on a portion of the bottom surface of the trench 120 are removed by an etching process, so as to form a spacer 181 on the sidewalls of the trench 120 and to expose the portion of the bottom surface of the trench 120. In one embodiment, the composition of the spacer 181 is, for example, silicon oxide, silicon nitride, silicon oxynitride, or a combination thereof. Afterwards, in the step S111, using the patterned mask 171 and the spacer 181 as a mask, an ion implantation process 180 is performed on the inner region 105-1 of the current spreading layer 105 through the trench 120, and dopants of the first conductivity type (such as P-type) are implanted into the inner region 105-1 to form a heavily doped region 115 of the first conductivity type (such as P-type) directly below the trench 120. In one embodiment, the doping concentration of the heavily doped region 115 is, for example, in a range of about 1E17 to about 1E19 atoms/cm³, but not limited thereto. The doping concentration of the heavily doped region 115 may be reduced to a range of about 1E16 to about 1E18 atoms/cm³ for reducing the resistance of the JFET effect produced between the bottom corners of the trench 120 and the well regions 107. According to some embodiments of the present disclosure, the width of the heavily doped region 115 may be controlled by adjusting the thickness of the spacer 181. When the thickness of the spacer 181 is larger, the width of the heavily doped region 115 is smaller. Moreover, in the first direction (for example, the X-axis direction), the width of the heavily doped region 115 is smaller than the width of the trench 120. In addition, the inner region 105-1 with the lowest doping concentration in the current spreading layer 105 surrounds the bottom corners of the trench 120 and the heavily doped region 115.

Then, referring to FIG. 8, in step S113, the patterned mask 171 and the spacer 181 are removed by a stripped process to expose the source contact regions 111, the bulk contact regions 113, the sidewalls and the bottom surface of the trench 120, and the heavy Doped region 115. In one embodiment, when the compositions of the patterned mask 171 and the spacer 181 are the same, for example, both are silicon oxide, the patterned mask 171 and the spacer 181 may be removed simultaneously by using the same stripping process. Thereafter, an annealing process may be performed to activate the dopants in all the source contact regions 111, the bulk contact regions 113 and the heavily doped region 115.

Still referring to FIG. 8, next, in step S115, a material layer of forming a gate dielectric layer 117 is conformally deposited on the surfaces of the source contact regions 111 and the bulk contact regions 113, and on the sidewalls and the bottom surface of the trench 120. In one embodiment, the composition of the gate dielectric layer 117 is, for example, silicon oxide. Next, a material layer of forming a gate electrode 119 is deposited on the material layer of the gate dielectric layer 117, which covers the source contact regions 111 and the bulk contact regions 113 and fills up the trench 120. In one embodiment, the composition of the gate electrode 119 is, for example, polysilicon. Then, in one embodiment, an etching process may be used to remove a portion of the material layer of the gate electrode 119 covering the source contact regions 111 and the bulk contact regions 113, so that the top surface of the gate electrode 119 formed in the trench 120 and the top surfaces of the source contact regions 111 and the bulk contact regions 113 may be substantially at the same level in the height. In another embodiment, a portion of the material layer of the gate electrode 119 covering the source contact regions 111 and the bulk contact regions 113 may be removed by a chemical mechanical planarization (CMP) process, and the gate dielectric layer 117 and the gate electrode 119 are remained in the trench 120, so that the top surface of the gate dielectric layer 117 and the top surface of the gate electrode 119 are substantially level with the top surfaces of the source contact regions 111 and the bulk contact regions 113.

Next, referring to FIG. 9, in step S117, an interlayer dielectric (ILD) layer 122 is deposited on the source contact regions 111, the bulk contact regions 113, the gate dielectric layer 117 and the gate electrode 119. Then, multiple contact openings 121 are formed in the ILD layer 122 by photolithography and etching processes, where a portion of the source contact region 111 and a portion of the bulk contact region 113 are exposed by each of the contact openings 121. In some embodiments, the composition of the ILD layer 122 is, for example, silicon oxide or other suitable low-k dielectric materials. In one embodiment, when the material layer of the gate dielectric layer 117 is left on the surfaces of the source contact regions 111 and the bulk contact regions 113, the etching process for forming the contact openings 121 also remove the material layer of the gate dielectric layer 117 located at the predetermined regions of forming the contact openings 121.

Next, referring to FIG. 10, in step S119, firstly, a barrier layer 123 is conformally deposited on the sidewalls and the bottom surfaces of the contact openings 121, and then the contact openings 121 are filled up with a conductive material by deposition and etching-back processes to form via holes 124. Afterwards, a metal wire layer including a source electrode 126 is formed on the ILD layer 122 by deposition, photolithography and etching processes, where the source electrode 126 is electrically coupled to both the source contact region 111 and the bulk contact region 113 through the same via hole 124. In addition, in the step S119, other via holes and other metal wires may also be formed to be electrically coupled to the heavily doped region 115, so that the heavily doped region 115 is electrically coupled to the source electrode 126 or a ground terminal, thereby further providing better electric field shielding effect by the heavily doped Region 115. In some embodiments, the composition of the barrier layer 123 is, for example, tantalum (Ta), tantalum nitride (TaN), titanium (Ti), titanium nitride (TiN) or other suitable diffusion barrier materials. The composition of the via holes 124 is, for example, tungsten (W), aluminum (Al), copper (Cu), aluminum copper (AlCu) or other suitable conductive materials. The composition of the source electrode 126 is, for example, aluminum copper (AlCu), aluminum (Al), copper (Cu) or other suitable conductive metal materials. In addition, when the size of the via hole 124 is small, such as less than 0.6 micrometer (μm), the via hole 124 may be formed from tungsten (W). When the size of the via hole 124 is relatively large, such as greater than 0.6 μm, the via hole 124 and the source electrode 126 may be formed simultaneously from aluminum copper (AlCu). Afterwards, a drain electrode 128 is formed on the bottom surface of the drain contact region 103 located on the second surface 110B of the substrate 110 by a deposition process, so as to complete the semiconductor device 100 of FIG. 1.

According to some embodiments of the present disclosure, the semiconductor device includes the heavily doped region directly below the trench and having a width smaller than the width of the trench. The semiconductor device further includes the current spreading layer surrounding the bottom corners of the trench and the heavily doped region, and having a laterally gradual doping concentration. Through the combination of the heavily doped region having the smaller width and the inner region of the current spreading layer having the lowest doping concentration, the resistance of the JFET effect produced between the bottom corners of the trench and the well region is reduced, and the electric field at the bottom of the trench gate is also effectively reduced, thereby improving the breakdown voltage and the reliability of the semiconductor device. In addition, those regions of the current spreading layer having higher doping concentrations also achieve the effect of spreading the current, thereby reducing the on-state resistance (Ron) of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a first surface and a second surface;
a trench, disposed in the substrate;
a gate electrode, disposed in the trench;
a source contact region, disposed on the first surface of the substrate;
a drain contact region, disposed on the second surface of the substrate;
a heavily doped region, having a first conductivity type and disposed directly below the trench, wherein a width of the heavily doped region is smaller than a width of the trench in a first direction; and
a current spreading layer, having a second conductivity type, disposed in the substrate and surrounding a bottom of the trench and the heavily doped region, wherein the current spreading layer has a gradual doping concentration that is gradually increased from the heavily doped region to an outside of the current spreading layer along the first direction.

2. The semiconductor device of claim 1, wherein the current spreading layer comprises an inner region in a direct contact with the heavily doped region and bottom corners of the trench, and the inner region has a lowest doping concentration in the current spreading layer.

3. The semiconductor device of claim 2, wherein the substrate includes an epitaxial layer having the second conductivity type, located between the drain contact region and the current spreading layer, and the lowest doping concentration of the inner region is lower than a doping concentration of the epitaxial layer.

4. The semiconductor device of claim 3, wherein the current spreading layer comprises an outer region having a highest doping concentration in the current spreading layer, and the highest doping concentration of the outer region is higher than the doping concentration of the epitaxial layer.

5. The semiconductor device of claim 2, further comprising a gate dielectric layer confirmally disposed on sidewalls and a bottom surface of the trench, and surrounding the gate electrode, wherein the gate dielectric layer is located between the gate electrode and the inner region of the current spreading layer.

6. The semiconductor device of claim 1, wherein the width of the heavily doped region is smaller than a width of the gate electrode in the first direction.

7. The semiconductor device of claim 1, further comprising:
a well region, having the first conductivity type, disposed in the substrate and abutting a side of the trench;
a bulk contact region, having the first conductivity type, disposed in the well region and abutting the source contact region; and
a source electrode, electrically coupled to both the source contact region and the bulk contact region.

8. The semiconductor device of claim 1, further comprising:
another trench, disposed in the substrate; and
another gate electrode, disposed in the another trench,
wherein a pitch is between the trench and the another trench, and the width of the heavily doped region is decreased as the pitch is decreased.

9. A method of fabricating a semiconductor device, comprising:
providing a wafer comprising a drain contact region, a first epitaxial layer and a second epitaxial layer stacked in sequence from bottom to top;
forming a patterned mask on the second epitaxial layer, wherein the patterned mask comprises a plurality of openings, and widths of the plurality of openings are increased sequentially from an inside to an outside of the patterned mask in a first direction;
performing an ion implantation process on the second epitaxial layer through the plurality of openings of the patterned mask to form a plurality of doped regions;
depositing a third epitaxial layer on the second epitaxial layer, wherein the plurality of doped regions and the second epitaxial layer form a current spreading layer having a gradual doping concentration that is gradually increased from an inside to an outside of the current spreading layer along the first direction;
forming a source contact region in the third epitaxial layer;
forming a trench to pass through the third epitaxial layer and to reach into the current spreading layer;
forming a heavily doped region directly below the trench, wherein a width of the heavily doped region is smaller than a width of the trench in the first direction; and
forming a gate electrode in the trench.

10. The method of claim 9, wherein the heavily doped region has a first conductivity type, the first epitaxial layer, the second epitaxial layer and the plurality of doped regions all have a second conductivity type, and a doping concentration of the second epitaxial layer is higher than a doping concentration of the first epitaxial layer.

11. The method of claim 9, wherein before depositing the third epitaxial layer, the plurality of doped regions are laterally separated from each other in the second epitaxial layer and have the same doping concentration, after depositing the third epitaxial layer, dopants in the plurality of doped regions are diffuses to form the gradual doping concentration of the current spreading layer.

12. The method of claim 9, wherein the patterned mask comprises a plurality of shielding portions, widths of the plurality of shielding portions are decreased sequentially from the inside to the outside of the patterned mask in the first direction, and an inner region of the current spreading layer having a lowest doping concentration is formed directly below a shielding portion of the patterned mask having a maximum width.

13. The method of claim 12, wherein the lowest doping concentration of the inner region of the current spreading layer is the same as a doping concentration of the second epitaxial layer.

14. The method of claim 12, wherein the inner region of the current spreading layer having the lowest doping concentration surrounds the heavily doped region and bottom corners of the trench.

15. The method of claim 9, wherein an outer region of the current spreading layer having a highest doping concentration is formed directly below an opening of the patterned mask having a maximum width.

16. The method of claim 9, wherein forming the heavily doped region comprises:
forming a spacer on sidewalls of the trench to expose a portion of a bottom surface of the trench; and
performing an ion implantation process on the current spreading layer through the portion of the bottom surface of the trench to form the heavily doped region.

17. The method of claim 16, further comprising:
after the heavily doped region is formed, removing the spacer; and
after removing the spacer, conformally forming a gate dielectric layer on the sidewalls and the bottom surface of the trench, wherein the gate electrode is formed on the gate dielectric layer.

18. The method of claim 9, further comprising:
forming a bulk contact region in the third epitaxial layer and abutting the source contact region; and
forming a source electrode to be electrically coupled to both the source contact region and the bulk contact region.
